(19) United States
(12) Patent Application Publication
(10) Pub. No.: US 2010/0059251 A1
(43) Pub. Date: Mar. 11, 2010

(54) PRINTED CIRCUIT BOARD AND MANUFACTURING METHOD

(75) Inventors: Sergey REMIZOV, Suwon-si (KR); Jae-Woo JOUNG, Suwon-si (KR); Hyun-Chul JUNG, Yongin-si (KR); Young-Ah SONG, Suwon-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/432,449

(22) Filed: Apr. 29, 2009

(30) Foreign Application Priority Data
Sep. 9, 2008 (KR) 10-2008-0088845

(51) Int. Cl. B29C 43/02; B29C 59/14; H05K 1/00

(52) U.S. Cl. 174/250; 264/447; 264/132

(57) ABSTRACT

Disclosed are a printed circuit board and a method for manufacturing the same. The method, which includes providing a base substrate in which a thermoplastic resin layer is formed; forming a circuit pattern on the thermoplastic resin layer by discharging a conductive ink by an inkjet method; curing the circuit pattern through the heating at a temperature that is lower than a melting point of the thermoplastic resin layer; sintering the circuit pattern through the heating; and burying at least a part of the circuit pattern in the thermoplastic resin layer by heating the thermoplastic resin layer and compressing the circuit pattern toward the thermoplastic resin layer, can provide a printed circuit board and a method for manufacturing the same, in which a fine circuit pattern can be formed by an inkjet method and the adhesive force between the circuit pattern and the base substrate can be improved.

### CROSS-REFERENCE TO RELATED APPLICATIONS

This application claims the benefit of Korean Patent Application No. 10-2008-0088845 filed with the Korean Intellectual Property Office on Sep. 9, 2008, the disclosure of which is incorporated herein by reference in its entirety.

### BACKGROUND

1. Technical Field

The present invention relates to a printed circuit board and a method of manufacturing the same.

2. Description of the Related Art

There have been many studies recently on forming a conductive pattern of a printed circuit board, an organic thin film transistor (OTFT), a radio frequency identification (RFID), a micro-electromechanical system (MEMS), and other electronic products by an inkjet method.

When the conductive pattern is formed on an insulating layer by the inkjet method, however, it is possible to form fine metal lines but it is difficult to provide sufficient adhesion between the insulating layer and the conductive pattern.

In accordance with the related art, the conductive pattern made of grains, in which nanoparticles of conductive ink are adhered to one another, is formed by allowing the conductive ink to be discharged to the insulating layer and to be cured and sintered by the inkjet method.

As the conductive pattern is made of grains according to the related art, the conductive pattern and the insulating layer are in point contact with each other. This causes the adhesive strength between the conductive pattern and the insulating layer to be significantly reduced.

### SUMMARY

The present invention provides a printed circuit board and a method for manufacturing the same in which a fine circuit pattern is formed by an inkjet method and the adhesive strength between the circuit pattern and a base substrate is improved.

An aspect of the invention features a method for manufacturing a printed circuit board, including providing a base substrate on which a thermoplastic resin layer is formed; forming a circuit pattern on the thermoplastic resin layer by discharging conductive ink by an inkjet method; heating and drying the circuit pattern at a temperature that is lower than a melting point of the thermoplastic resin layer; heating and sintering the circuit pattern; and burying at least a part of the circuit pattern in the thermoplastic resin layer by heating the thermoplastic resin layer and compressing the circuit pattern toward the thermoplastic resin layer.

In this case, the heating and sintering of the circuit pattern can be performed by heating the circuit pattern at a temperature that is lower than the melting point of the thermoplastic resin layer.

The burying of the circuit pattern can be performed by heating the thermoplastic resin layer at a temperature that is higher than the melting point of the thermoplastic resin layer.

At this time, the method can further include, between the providing of the base substrate and the forming of the circuit pattern, surface treating the thermoplastic resin layer such that a surface of the thermoplastic resin layer becomes hydrophobic.

The surface treating of the thermoplastic resin layer can include plasma treating the surface of the thermoplastic resin layer.

The surface treating of the thermoplastic resin layer can include forming a hydrophobic material layer on the thermoplastic resin layer.

In this case, the hydrophobic material layer can include flouro-resin.

The thermoplastic resin layer can be a film, and the providing of the base substrate can include stacking the thermoplastic resin layer on the base substrate.

Another aspect of the invention features a printed circuit board, including a base substrate; a thermoplastic resin layer, being formed on the base substrate; and a circuit pattern, having at least a part thereof being buried in the thermoplastic resin layer and being formed on the thermoplastic resin layer by discharging conductive ink by an inkjet method.

In this case, a sintering temperature of the circuit pattern can be lower than a melting point of the thermoplastic resin layer.

The thermoplastic resin layer can be a film.

### BRIEF DESCRIPTION AND THE DRAWINGS

FIG. 1 is a flowchart showing a method for manufacturing a printed circuit board according to an embodiment based on an aspect of the present invention.

FIG. 2 through FIG. 6 are cross-sectional views showing each process of a method for manufacturing a printed circuit board according to an embodiment based on an aspect of the present invention.

FIG. 7 is a partially enlarged view showing an area A of FIG. 6.

FIG. 8 is a cross-sectional view showing a printed circuit board according to an embodiment based on another aspect of the present invention.

### DETAIL DESCRIPTION

A printed circuit board and a method for manufacturing the printed circuit board according to certain embodiments of the invention will be described below in detail with reference to the accompanying drawings. Those elements that are the same or are in correspondence are rendered the same reference numeral regardless of the figure number, and redundant explanations can be omitted.

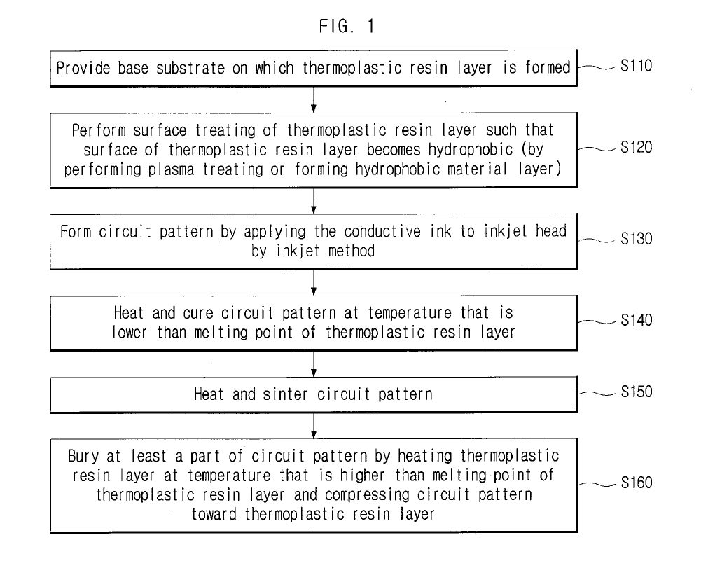

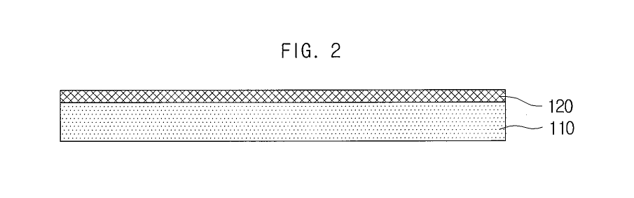

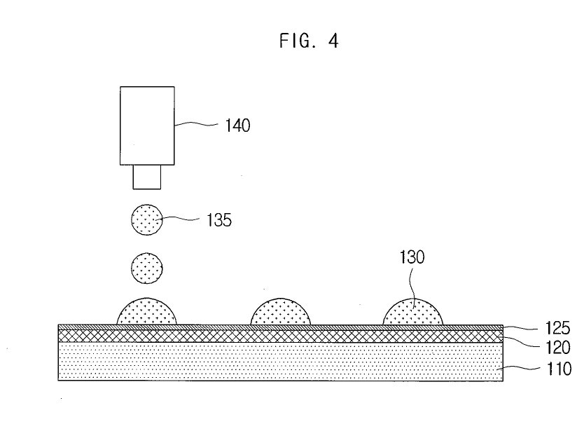

FIG. 1 is a flowchart showing a method for manufacturing a printed circuit board according to an embodiment based on an aspect of the present invention, and FIG. 2 through FIG. 6 are cross-sectional views showing each process of a method for manufacturing a printed circuit board according to an embodiment based on an aspect of the present invention.

In accordance with this embodiment of the present invention, the method of manufacturing the printed circuit board can include providing a base substrate 110, on which a thermoplastic resin layer 120 is formed, forming a circuit pattern 130 on the thermoplastic resin layer 120 by discharging conductive ink 135 by use of an inkjet method, heating and curing the circuit pattern 130 at a temperature that is lower than the melting point of the thermoplastic resin layer 120, heating and sintering the circuit pattern 130, and burying at least a part of the circuit pattern 130′ in the thermoplastic resin layer 120 by heating the thermoplastic resin layer 120 at a temperature that is higher than the melting point and compressing the part of the circuit pattern 130′ toward the thermoplastic resin layer 120.

As such, in accordance with this embodiment of the present invention, it can be possible to finely and precisely form the circuit 130 or 130′ by the inkjet method. At this time, using the thermoplastic resin layer 120 can improve the adhesive strength between the circuit pattern 130 and the base substrate 110.

Hereinafter, each process will be described in more detail with reference to FIG. 1 through FIG. 7.

A process represented by S110 can provide the base substrate 110 on which the thermoplastic resin layer 120 is formed as shown in FIG. 2. Instead of directly forming the circuit pattern 130 on the base substrate 110, the circuit pattern 130 can be first formed on the thermoplastic resin layer 120 formed on the base substrate 110. Then, at least a part of the circuit pattern 130′ can be buried in the thermoplastic resin layer 120. Accordingly, it is possible to improve the adhesive strength between the circuit pattern 130 and the base substrate 110.

Here, the thermoplastic resin layer 120 can be made of, for example, polyimide, polyester, or polyvinyl butyral. The thermoplastic resin layer 120 can be also made of a material having a melting point that is higher than the sintering temperature of the circuit pattern 130, which is described below. Accordingly, the thermoplastic resin layer 120 may not be melted in a process of sintering the circuit pattern 130, which is described below, and the phase of the thermoplastic resin layer 120 can be maintained.

Since the thermoplastic resin layer 120 has a film shape, it is possible to more easily provide the base substrate 110, on which the thermoplastic resin layer 120 is formed, by simply stacking the thermoplastic resin layer 120 on the base substrate 110.

This embodiment of the present invention suggests the case that the thermoplastic resin layer 120 is a film as an example. Of course, the thermoplastic resin layer 120 can be also formed on the base substrate 110 by processing a liquid crystal by various known methods such as spraying, dipping, spin coating, screen printing, or inkjet printing.

The base substrate 110 can be an insulating layer made of, for example, FR4 or a bismaleimide triazine resin.

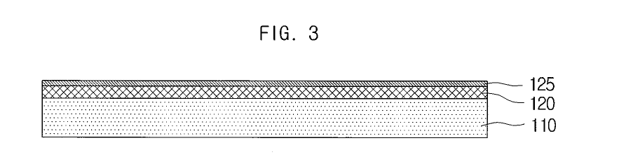

Next, a process represented by S120 can surface treat the thermoplastic resin layer 120 such that the surface of the thermoplastic resin layer 120 becomes hydrophobic, as shown in FIG. 3. Since the liquid-phase circuit pattern 130 is formed on the thermoplastic resin layer 120 by the inkjet method, it may be required to surface treat the thermoplastic resin layer 120 such that the thermoplastic resin layer 120 has a hydrophobic surface in order to prevent the circuit pattern 130 formed by the inkjet method from being scattered on the thermoplastic resin layer 120.

As such, as the thermoplastic resin layer 120 has the hydrophobic surface through the surface treatment, the liquid-phase conductive ink 135 can be cohered on the thermoplastic resin layer 120 instead of being scattered. This can make it possible to form the finer and more precise circuit pattern 130 or 130′.

The aforementioned surface treatment can be performed by forming a hydrophobic material layer 125. The hydrophobic material layer 125 formed on the thermoplastic resin layer 120 can be made of flouro-resin, such as polytetrafluoroethylene (PTFE), perfluoroalkoxy (PFA), fluorinated ethylenepropylene (FEP) and a combination thereof.

The hydrophobic material layer 125 can be also formed on the base substrate 110 by processing a liquid crystal by various known methods such as spraying, dipping, spin coating, screen printing, or inkjet printing, to the aforementioned thermoplastic resin layer 120.

Moreover, in addition to the formation of the aforementioned hydrophobic material layer 125, the surface treatment of the thermoplastic resin layer 120 can be performed by plasma treating a surface of the thermoplastic resin layer 120. In other words, the thermoplastic resin layer 120 can have a hydrophobic surface by performing the flouro plasma treatment of the surface of the thermoplastic resin layer 120.

Next, a process represented by S130 can form the circuit pattern 130 by discharging the conductive ink 135 from an inkjet head 140 by an inkjet method. Since the thermoplastic resin layer 120 has the hydrophobic surface through the surface treatment, if the conductive ink 135 is discharged to the thermoplastic resin layer 120 by the inkjet method, the circuit pattern formed on the thermoplastic resin layer 120 can be cohered on the thermoplastic resin layer 120 instead of being scattered. This can make it possible to form the finer and more precise circuit pattern 130.

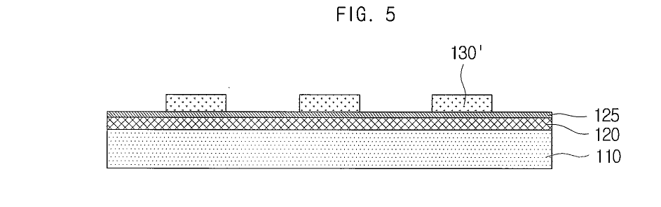

Next, a process represented by S140 can heat and cure the circuit pattern 130 at a temperature that is lower than the melting point of the thermoplastic resin layer 120, as shown in FIG. 5. Then, a process represented by S150 can heat and sinter the circuit pattern 130. Hereinafter, each process will be further described.

Firstly, the process represented by S140 can heat and cure the circuit pattern 130. This is to cure the circuit pattern 130 by heating, for example, the base substrate 110 to allow the circuit pattern 130 formed on the thermoplastic resin layer 120 to become finer.

At this time, the circuit pattern 130 may be required to be heated at a temperature that is lower than the melting point of the thermoplastic resin layer 120 in order to allow the thermoplastic resin layer 120 not to be melted and maintain the solid phase, thereby more precisely manufacturing the printed circuit board 100.

Then, the process represented by S150 can sinter the circuit board 130 through the heating. The sintering can make nanoparticles adhered to one another, thereby forming the hardened circuit pattern 130′.

At this time, atmosphere gas and/or pressure can be used to prevent the circuit pattern 130 or 130′ from being oxidized.

The sintering temperature of the circuit pattern may be lower than the melting point of the thermoplastic resin layer 120. Accordingly, it is possible to prevent the thermoplastic resin layer 120 from being melted and to maintain the solid phase, thereby more precisely manufacturing the printed circuit board 100.

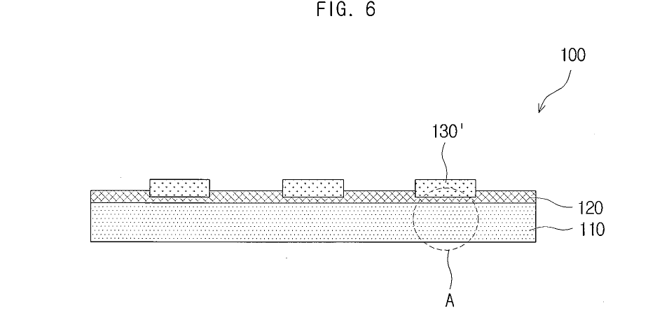

Next, a process represented by S160 can bury at least a part of the circuit pattern 130′ by heating the thermoplastic resin layer 120 at a temperature that is higher than the melting point and compressing the part of the circuit pattern 130′ toward the thermoplastic resin layer 120, as shown in FIG. 6.

In other words, the circuit pattern 130′ can be buried in the thermoplastic resin layer 120 by heating the thermoplastic resin layer 120 and compressing the part of the circuit pattern 130′ toward the thermoplastic resin layer 120 by use of, for example, a press.

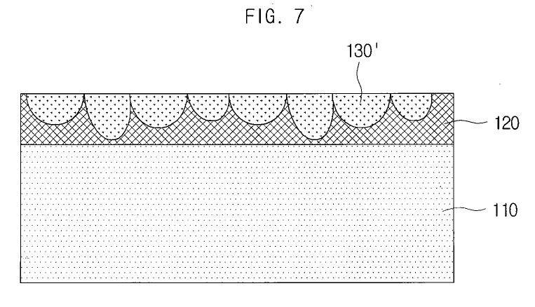

Hereinafter, this process will be described in more detail with reference to FIG. 6 and FIG. 7.

The thermoplastic resin layer 120 can be converted to a liquid phase having fluidity when heated at a temperature that is equal to or greater than the melting point. This can make it possible to compress the circuit pattern 130′ toward the thermoplastic resin layer 120 and to bury the circuit pattern 130′ in the thermoplastic resin layer 120. Accordingly, an area in which the circuit pattern 130′ is adhered to the thermoplastic resin layer 120 can be broadened, thereby increasing the adhesive strength between the circuit pattern 130′ and the base substrate 110.

In this case, a part of the circuit pattern 130′ as shown in FIG. 6 or the entire area of the circuit pattern 130′ can be buried in the thermoplastic resin layer 120.

The hydrophobic material layer 125 being formed for the surface treatment of the thermoplastic resin layer 120 may be scattered on the thermoplastic resin layer 120 by the heating. Accordingly, the hydrophobic material layer 125 may not remain on the surface of the thermoplastic resin layer 120. Thus, after the circuit pattern 130′ is buried, the hydrophobic material layer 125 may have no effect on the adhesive strength between the circuit pattern 130′ and the thermoplastic resin layer 120.

FIG. 7 is a partially enlarged view showing an area A of FIG. 6. As shown in FIG. 7, the circuit pattern 130′ can be buried in the thermoplastic resin layer 120 in a wide area in which the circuit pattern 130′ is adhered to the thermoplastic resin layer 120. In other words, nanoparticles can be adhered to one another by being cured as grains having a predetermined size in the circuit pattern 130′ being formed by an inkjet method. Accordingly, the grains can penetrate into the thermoplastic resin layer 120, thereby improving the adhesiveness.

As an example of this embodiment in accordance with the present invention, the circuit pattern 130′ is buried in the thermoplastic resin layer 120 by heating the thermoplastic resin layer 120 at a temperature that is higher than the melting point of the thermoplastic resin layer 120. The circuit pattern 130′, however, can be also buried in the thermoplastic resin layer 120 by adjusting the pressure instead of heating the thermoplastic resin layer 120 at a temperature that is higher than the melting point of the thermoplastic resin layer 120. Of course, this is also included in the spirit and scope of the claims of the present invention.

Hereinafter, this embodiment of the present will be described through an example of a specific experiment.

### Experiment 1

The thermoplastic resin layer 120 made of polyvinyl butyral is coated on the base substrate 110 made of bismaleimide triazine resin. Then, the circuit pattern 130 is formed by an inkjet method and is cured and sintered at the temperature of 200° C. in the reducing atmosphere. Thereafter, a part of the circuit pattern 130′ is buried in the thermoplastic resin layer 120 at the temperature of 200° C. and under the pressure of 20 MPa.

The bonding strength between the circuit pattern 130′ and the thermoplastic resin layer 120 in the printed circuit board manufactured by the aforementioned operations is tested to have been increased to 1.1 N/mm. For the reference, in the case of using no thermoplastic resin layer 120 and the circuit pattern 130′ that is not buried, the bonding strength was 0.11 N/mm.

Next, a printed circuit board will be described according to an embodiment based on another aspect of the present invention

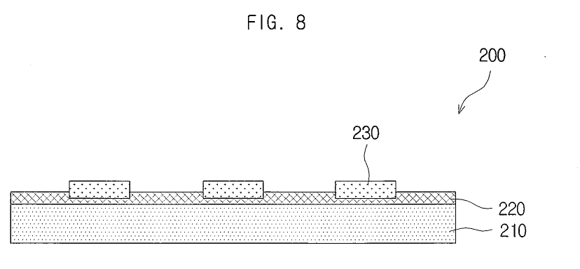

FIG. 8 is a cross-sectional view showing a printed circuit board according to an embodiment based on another aspect of the present invention.

In accordance with this embodiment of the present invention, a printed circuit board 200 can include a base substrate 210, a thermoplastic resin layer 220, which is formed on the base substrate 210, and a circuit pattern 230, which has at least a part thereof buried in the thermoplastic resin layer 220 and formed by discharging conductive ink on the thermoplastic resin layer 220 by an inkjet method.

As such, it is possible to manufacture the printed circuit board 200 according to this embodiment of the present invention in which the circuit pattern 230 formed finely and precisely by the inkjet method can be strongly adhered to the base substrate 210 by the thermoplastic resin layer 220.

Hereinafter, each element will be described in more detail with reference to FIG. 8.

The base substrate 210 can be an insulating layer made of, for example, FR4 or a bismaleimide triazine resin. The thermoplastic resin layer 220 can be formed on the base substrate 210 in order to improve the adhesive strength between the circuit pattern, which is formed by the inkjet method, and the base substrate 210.

The thermoplastic resin layer 220 can be made of, for example, polyimide, polyester, or polyvinyl butyral. In this case, since the thermoplastic resin layer 220 has a film shape, the thermoplastic resin layer 220 can be more easily formed on the base substrate 210, by simply stacking the thermoplastic resin layer 220 on the base substrate 210.

A circuit pattern 230 can be formed by discharging conductive ink on the thermoplastic resin layer 220 by the inkjet method. At least a part of the circuit pattern 230 can be buried in the thermoplastic resin layer 220.

In other words, in the circuit pattern 230, conductive ink nanoparticles can be adhered to one another as grains by discharging the conductive ink by the inkjet method and then curing and sintering the discharged conductive ink. A part of the circuit pattern 230 can be buried in the thermoplastic resin layer 220 by heating the thermoplastic resin layer 220 and compressing the circuit pattern 230 toward the thermoplastic resin layer 220. Accordingly, an area in which the circuit pattern 230 is adhered to the thermoplastic resin layer 220 can be broadened, thereby increasing the adhesive strength between the circuit pattern 230 and the base substrate 210. At this time, the entire area of the circuit pattern 230 can be buried in the thermoplastic resin layer 220.

The sintering temperature of the circuit pattern 230 may be lower than the melting point of the thermoplastic resin layer 220. Accordingly, even though the circuit pattern 230 is cured, it is possible to prevent the thermoplastic resin layer 120 from being melted and maintain its phase, thereby more easily manufacturing the precise printed circuit board 200.

In accordance with this embodiment of the present invention, the printed circuit board 200 can be manufactured through an embodiment of the method of manufacturing the printed circuit board 100 (refer to FIG. 1). Accordingly, the detailed description related to the method of manufacturing the printed circuit board 200 in accordance with this embodiment will be omitted.

Hitherto, although some embodiments of the present invention have been shown and described, it shall be appreciated by any person of ordinary skill in the art that a large number of modifications, permutations and additions are possible within the principles and spirit of the invention, the scope of which shall be defined by the appended claims and their equivalents. These are also included in the spirit and scope of the claims of the present invention.

What is claimed is:

1. A method for manufacturing a printed circuit board, the method comprising:
providing a base substrate on which a thermoplastic resin layer is formed;
forming a circuit pattern on the thermoplastic resin layer by discharging conductive ink by an inkjet method;
heating and drying the circuit pattern at a temperature that is lower than a melting point of the thermoplastic resin layer;
heating and sintering the circuit pattern; and
burying at least a part of the circuit pattern in the thermoplastic resin layer by heating the thermoplastic resin layer and compressing the circuit pattern toward the thermoplastic resin layer.

2. The method of claim 1, wherein the heating and sintering of the circuit pattern is performed by heating the circuit pattern at a temperature that is lower than the melting point of the thermoplastic resin layer.

3. The method of claim 1, wherein the burying of the circuit pattern is performed by heating the thermoplastic resin layer at a temperature that is higher than the melting point of the thermoplastic resin layer.

4. The method of claim 1, further comprising, between the providing of the base substrate and the forming of the circuit pattern, surface treating the thermoplastic resin layer such that a surface of the thermoplastic resin layer becomes hydrophobic.

5. The method of claim 4, wherein the surface treating of the thermoplastic resin layer comprises plasma treating the surface of the thermoplastic resin layer.

6. The method of claim 4, wherein the surface treating of the thermoplastic resin layer comprises forming a hydrophobic material layer on the thermoplastic resin layer.

7. The method of claim 6, wherein the hydrophobic material layer comprises flouro-resin.

8. The method of claim 1, wherein the thermoplastic resin layer is a film, and
the providing of the base substrate comprises stacking the thermoplastic resin layer on the base substrate.

9. A printed circuit board, comprising:
a base substrate;
a thermoplastic resin layer, being formed on the base substrate; and
a circuit pattern, having at least a part thereof being buried in the thermoplastic resin layer and being formed on the thermoplastic resin layer by discharging conductive ink by an inkjet method.

10. The printed circuit board of claim 9, wherein a sintering temperature of the circuit pattern is lower than a melting point of the thermoplastic resin layer.

11. The printed circuit board of claim 9, wherein the thermoplastic resin layer is a film.
